(19) United States
(12) Patent Application Publication
(10) Pub. No.: US 2022/0059916 A1
(43) Pub. Date: Feb. 24, 2022

(54) TRANSMISSION LINE AND ELECTRONIC APPARATUS

(71) Applicant: KABUSHIKI KAISHA TOSHIBA, Tokyo (JP)

(72) Inventor: Koh HASHIMOTO, Yokohama Kanagawa (JP)

(73) Assignee: KABUSHIKI KAISHA TOSHIBA, Tokyo (JP)

(21) Appl. No.: 17/187,633

(22) Filed: Feb. 26, 2021

(30) Foreign Application Priority Data
Aug. 21, 2020 (JP) 2020-140412

(51) Int. Cl. H01P 3/08; H01Q 13/10; H05K 1/02

(52) U.S. Cl. CPC H01P 3/08; H05K 2201/10098; H05K 1/0243; H01Q 13/106

(57) ABSTRACT

According to one embodiment, a transmission line includes a substrate; a first transmission conductor on a first surface of the substrate; first conductors penetrating from the first surface of the substrate to a second surface of the substrate on an opposite side from the first surface; second conductors on a side opposite to the first conductors with respect to the first transmission conductor, and penetrating from the first surface to the second surface; a first conductive member forming a first space surrounding the first transmission conductor, and electrically connecting the first conductors and the second conductors; and a second conductive member forming a second space surrounding a region on the second surface of the substrate, the region opposing to the first transmission conductor, and electrically connecting the first conductors and the second conductors.

### CROSS REFERENCE TO RELATED APPLICATIONS

This application is based upon and claims the benefit of priority from the prior Japanese Patent Application No. 2020-140412, filed on Aug. 21, 2020, the entire contents of which are incorporated herein by reference.

### FIELD

Embodiments described herein relates to a transmission line and an electronic apparatus.

### BACKGROUND

A rectangular transmission line is known where a dielectric having a conductor strip is disposed in the inside of a hollow rectangular waveguide. For example, a rectangular coaxial line is known that includes a U-groove-shaped outer conductor, a side wall outer conductor, and a dielectric having inner conductors formed on the front surface and the rear surface thereof.

In this configuration, an inner conductor support dielectric is inserted into a small groove formed on the inner wall of the U-groove-shaped outer conductor. Therefore, there is a problem that when the frequency used is high (for example, in a case of a quasi-millimeter wave band or a millimeter wave band), it is difficult to manufacture a rectangular coaxial line. It is also difficult to manufacture a bend structure or a branch structure. Further, the outer conductor of the rectangular coaxial line is formed of a plurality of conductor components. Therefore, there is a problem that if the conductor components are not electrically connected, a portion of an electromagnetic wave that propagates the inside of the rectangular coaxial line leaks through a gap formed between the conductor components, thus increasing transmission loss.

Other rectangular coaxial line is also known where a center conductor is formed by coating and forming a metal strip conductor on the upper surface and the lower surface of a dielectric substrate, and the center conductor is disposed in a space in an outer conductor formed of a rectangular waveguide. However, a method for supporting the dielectric substrate forming the center conductor is unknown and hence, it is difficult to manufacture such a rectangular coaxial line.

### BRIEF DESCRIPTION OF THE DRAWINGS

FIG. 1 is an exploded perspective view of a rectangular coaxial line which is a coaxial line according to a first embodiment;

FIG. 2 is an xz cross-sectional view of the rectangular coaxial line shown in FIG. 1;

FIG. 3 is an exploded perspective view of a rectangular coaxial line of a second embodiment;

FIG. 4 is an xz cross-sectional view of the rectangular coaxial line shown in FIG. 3;

FIG. 5 is an exploded perspective view of a rectangular coaxial line which is a coaxial line according to a third embodiment;

FIG. 6 is an xz cross-sectional view of the rectangular coaxial line shown in FIG. 5;

FIG. 7 is an exploded perspective view of a rectangular coaxial line which is a coaxial line according to a fourth embodiment;

FIG. 8 is an xz cross-sectional view of the rectangular coaxial line shown in FIG. 7;

FIG. 9 is an exploded perspective view of a rectangular coaxial line which is a coaxial line according to a fifth embodiment;

FIG. 10 is an xz cross-sectional view of the rectangular coaxial line shown in FIG. 9;

FIG. 11 is an exploded perspective view of a rectangular coaxial line (array antenna) which is a coaxial line according to a sixth embodiment; and

FIG. 12 is a top plan view of the rectangular coaxial line shown in FIG. 11.

### DETAILED DESCRIPTION

According to one embodiment, a transmission line includes a substrate; a first transmission conductor, a plurality of first conductors, a plurality of second conductors, a first conductive member and a second conductive member.

The first transmission conductor is formed on a first surface of the substrate; a plurality of first conductors penetrate from the first surface of the substrate to a second surface of the substrate on an opposite side from the first surface.

The plurality of second conductors are on a side opposite to the plurality of first conductors with respect to the first transmission conductor, and penetrate from the first surface of the substrate to the second surface of the substrate.

The first conductive member forms a first space surrounding the first transmission conductor, and electrically connects the plurality of first conductors and the plurality of second conductors.

The second conductive member forms a second space surrounding a region on the second surface of the substrate, the region opposing to the first transmission conductor, and electrically connects the plurality of first conductors and the plurality of second conductors.

Hereinafter, embodiments of the present invention will be described with reference to drawings.

### First Embodiment

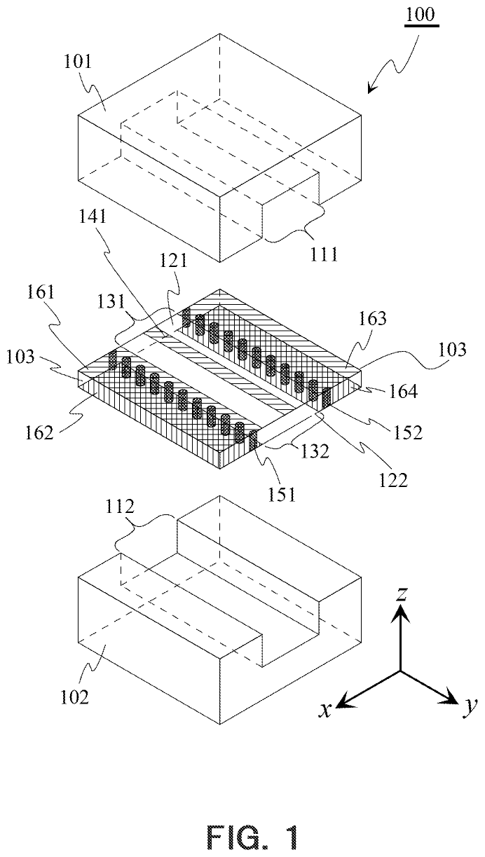

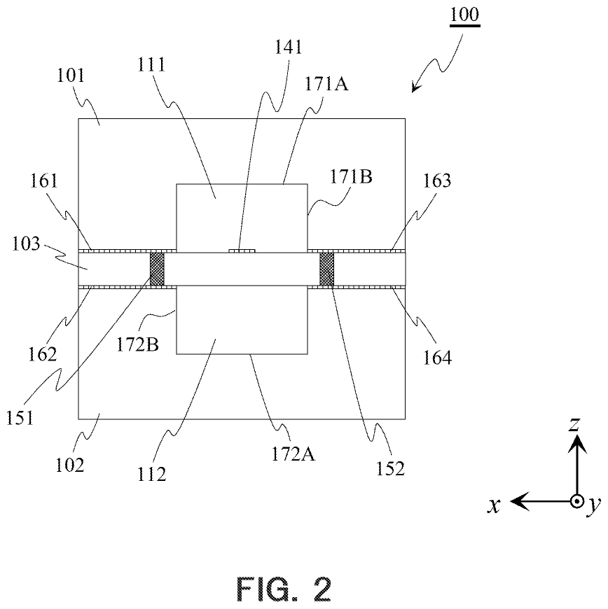

Hereinafter, a rectangular coaxial line 100 which is a coaxial line according to a first embodiment will be described with reference to FIG. 1 and FIG. 2.

FIG. 1 is an exploded perspective view of the rectangular coaxial line 100 which is the coaxial line according to the first embodiment. FIG. 2 is an xz cross-sectional view of the rectangular coaxial line 100 shown in FIG. 1.

The rectangular coaxial line 100 is a transmission line including a first conductive member 101, a second conductive member 102, and a substrate 103. The rectangular coaxial line allows propagation of a Quasi TEM mode, thus having an advantage that the dimension of the transmission line can be reduced more compared with a hollow rectangular waveguide or the like having a cutoff frequency. Further, an electric field is not easily concentrated in a substrate compared with a printed circuit board transmission line, such as a microstrip line, a strip line, a coplanar waveguide, a conductor-backed coplanar waveguide, and a post-wall waveguide (also referred to as SIW, Substrate Integrated Waveguide). Therefore, the rectangular coaxial line 100 has an advantage that loss can be reduced.

The substrate 103 is disposed to be sandwiched between the first conductive member 101 and the second conductive member 102. In other words, the rectangular coaxial line 100 has a configuration where the second conductive member 102, the substrate 103, and the first conductive member 101 are stacked in this order. Hereinafter, with respect to surfaces of the substrate 103, a surface (first surface) which faces (or opposes to) the first conductive member 101 is referred to as a first main surface 121, and a surface (second surface) which faces the second conductive member 102 is referred to as a second main surface 122.

For each of the first conductive member 101 and the second conductive member 102, it is possible to use a member which is made of metal such as copper or aluminum, or a resin whose surface is covered by conductive plating. From a viewpoint of suppressing transmission loss, it is preferable that the surface have high conductivity. It is also possible to adopt a configuration where a member is made of metal having low conductivity, and the surface of the member is plated with a material having high conductivity, such as copper or silver.

The substrate 103 is formed of an insulator. A dielectric may be used as a material for forming the substrate 103, for example. Additionally, it is also possible to use a resin substrate made of PTFE (polytetrafluoroethylene) or modified PPE (polyphenylene ether), a film substrate made of resin foam, liquid crystal polymer or COP (cycloolefin copolymer), ceramic, such as LTCC (Low Temperature Co-fired Ceramics) or HTCC (High Temperature Co-fired Ceramics), or glass.

A method for fixing or joining between the first conductive member 101, the second conductive member 102, and the substrate 103 may be such that holes penetrating in common alignment through the first conductive member 101, the second conductive member 102, and the substrate 103 are formed, and these members are fastened with each other by screws or the like. It may also be possible to adopt other method, such as bonding.

The first conductive member 101 has a first groove 111. The second conductive member 102 has a second groove 112. In an example shown in FIG. 1 and FIG. 2, each of the first groove 111 and the second groove 112 is a rectangular groove having uniform dimensions in the xz plane in the drawing. However, by taking into account manufacturing, the groove may have draft, or the corners of the bottom surface of the groove may be rounded. In the example shown in FIG. 1 and FIG. 2, the first groove 111 and the second groove 112 have the same depth (the dimension in the z axis direction). However, the first groove 111 and the second groove 112 may have different depths. In the example shown in FIG. 1 and FIG. 2, the first groove 111 and the second groove 112 are described as grooves, and these grooves are included in recesses. It may be described such that the first conductive member 101 has a first recess, and the second conductive member 102 has a second recess.

The first main surface 121 of the substrate 103 has a first region 131 being a region that the first groove 111 faces, and the first region 131 is provided with a first conductor strip 141 being a first transmission conductor. The first conductor strip 141 is positioned at the center or the substantially center of the first groove 111 and the second groove 112 as viewed in an xy plane. The first conductor strip 141 is made of metal, such as copper. The first conductor strip 141 may be formed by etching a copper clad substrate (subtractive method), or by additive method which forms a required pattern on a substrate having no copper foil. However, the first conductor strip 141 may be formed by other method.

A first conductive via row 151 is formed in the substrate 103 along the first conductor strip 141. The first conductive via row 151 is arranged along (corresponding to) the y axis direction (first direction). The first conductive via row 151 is formed of a plurality of first conductors that penetrate through the substrate 103 from the first main surface 121 to the second main surface 122 on the opposite side from the first main surface 121. The first conductive via row 151 is provided outside the first region 131, and outside a second region 132 on the second main surface 122, the second region 132 being a region that the second groove 112 faces. To be more specific, the first conductive via row 151 is provided in a region with x coordinates greater than x coordinates of the first region 131 and the second region 132. That is, the first conductive via row 151 is provided along the first groove 111 and the second groove 112 in the region with the x coordinates greater than x coordinates of the first groove 111 and the second groove 112.

A first conductor pattern 161 is provided between the first conductive member 101 and the first main surface 121, and the first conductor pattern 161 electrically connects the first conductive member 101 and the first conductive via row 151 with each other. The first conductive via row 151 is electrically connected with the first conductive member 101 via the first conductor pattern 161. A second conductor pattern 162 is provided between the second conductive member 102 and the second main surface 122, and the second conductor pattern 162 electrically connects the second conductive member 102 and the first conductive via row 151 with each other. The first conductive via row 151 is electrically connected with the second conductive member 102 via the second conductor pattern 162. That is, the first conductor pattern 161, the first conductive via row 151, and the second conductor pattern 162 are electrically connected.

A second conductive via row 152 is formed in the substrate 103 along the first conductor strip 141 on the side opposite to the first conductive via row 151 with respect to the first conductor strip 141. The second conductive via row 152 is arranged along (corresponding to) the y axis direction (first direction). The second conductive via row 152 is formed of a plurality of second conductors that penetrate through the substrate 103 from the first main surface 121 to the second main surface 122. The second conductive via row 152 is provided outside the first region 131, and outside the second region 132. To be more specific, the second conductive via row 152 is provided in a region with x coordinates less than x coordinates of the first region 131 and the second region 132. That is, the second conductive via row 152 is provided along the first groove 111 and the second groove 112 in the region with the x coordinates less than x coordinates of the first groove 111 and the second groove 112. In the example shown in FIG. 1, the first conductive via row 151 and the second conductive via row 152 are arranged along (corresponding to) the y axis direction (first direction). Even in a case where some conductive vias of these conductive via rows have different x coordinates, it is assumed that the first conductive via row 151 and the second conductive via row 152 are arranged along (corresponding to) the y axis direction (first direction). For example, even in a case where some conductive vias of the first conductive via row 151 have x coordinates deviated from x coordinates of other conductive vias of the first conductive via row 151, it is assumed that the first conductive via row 151 is arranged along (corresponding to) the y axis direction (first direction).

A third conductor pattern 163 is provided between the first conductive member 101 and the first main surface 121, and the third conductor pattern 163 electrically connects the first conductive member 101 and the second conductive via row 152 with each other. The second conductive via row 152 is electrically connected with the first conductive member 101 via the third conductor pattern 163. A fourth conductor pattern 164 is provided between the second conductive member 102 and the second main surface 122, and the fourth conductor pattern 164 electrically connects the second conductive member 102 and the second conductive via row 152 with each other. The second conductive via row 152 is electrically connected with the second conductive member 102 via the fourth conductor pattern 164. That is, the third conductor pattern 163, the second conductive via row 152, and the fourth conductor pattern 164 are electrically connected.

The first conductive member 101 uses the first groove 111 to form a space between the first conductive member 101 and the first conductor strip 141. Further, the first conductive member 101 is electrically connected with the first conductive via row 151 (a plurality of first conductors) and the second conductive via row 152. That is, the first conductive member 101 is a first enclosure member that forms a space along the first conductor strip 141, the space surrounding the first conductor strip 141 in the negative direction along the z axis (the direction in which the first conductive member 101 faces the first main surface 121). The first enclosure member electrically connects the first conductive via row 151 and the second conductive via row 152 with each other. Of the surfaces of the first conductive member 101, the surface having the first groove 111 corresponds to a lower surface (third surface) facing the first main surface 121 of the substrate 103. Of the surfaces of the first conductive member 101, the surface on the opposite side from the lower surface corresponds to an upper surface (fourth surface).

The second conductive member 102 uses the second groove 112 to form a space between the second conductive member 102 and a region on the second main surface 122 of the substrate 103 corresponding to the first conductor strip 141. Further, the second conductive member 102 is electrically connected with the first conductive via row 151 (the plurality of first conductors) and the second conductive via row 152. That is, the second conductive member 102 is a second enclosure member that forms a space along the above-mentioned region, where the second main surface 122 faces the first conductor strip 141, the space surrounding the above-mentioned region, where the second main surface 122 faces the first conductor strip 141, in the positive direction (the direction in which the second conductive member 102 faces the second main surface 122) along the z axis. The second enclosure member electrically connects the first conductive via row 151 and the second conductive via row 152 with each other.

An example of a method for forming the first conductive via row 151 and the second conductive via row 152 may be such that holes are formed in the substrate 103 using a drill or the like, and the inner wall surfaces of the holes are plated. Alternatively, the first conductive via row 151 and the second conductive via row 152 may be formed by filling the holes with a conductor or a conductive resin. A method for forming the first conductor pattern 161, the second conductor pattern 162, the third conductor pattern 163, and the fourth conductor pattern 164 is substantially equal to the method for forming the first conductor strip 141.

The first conductor strip 141 corresponds to the inner conductor of the coaxial line. A top surface 171A and side surfaces 171B of the first groove 111 and a bottom surface 172A and side surfaces 172B of the second groove 112 correspond to the outer conductors of the coaxial line.

In the first conductive via row 151 and the second conductive via row 152, the diameter of each conductive via is smaller than the wavelength. Intervals between the conductive vias are also smaller than the wavelength. The first conductive via row 151 is electrically connected with the first conductor pattern 161 and the second conductor pattern 162. The first conductive member 101, the second conductive member 102, and the substrate 103 are fixed or joined such that the first conductive member 101 and the first conductor pattern 161 are brought into contact with each other, and the second conductive member 102 and the second conductor pattern 162 are brought into contact with each other. Therefore, an electric current flows from the first conductive member 101 to the second conductive member 102 through the first conductor pattern 161, the first conductive via row 151, and the second conductor pattern 162 and hence, it is possible to suppress leakage of radio waves toward the positive direction along the x axis. Further, the second conductive via row 152 is electrically connected with the third conductor pattern 163 and the fourth conductor pattern 164. The first conductive member 101, the second conductive member 102, and the substrate 103 are fixed or joined such that the first conductive member 101 and the third conductor pattern 163 are brought into contact with each other, and the second conductive member 102 and the fourth conductor pattern 164 are brought into contact with each other. Therefore, an electric current flows from the first conductive member 101 to the second conductive member 102 through the third conductor pattern 163, the second conductive via row 152, and the fourth conductor pattern 164 and hence, it is possible to suppress leakage of radio waves toward the negative direction along the x axis.

In FIG. 1 and FIG. 2, the rectangular coaxial line 100 is illustrated as a linear transmission line extending in the y axis direction. However, the rectangular coaxial line 100 may have at least one of either a bend or a branch. For example, in the case of forming the bend, the first groove 111, which is formed on the first conductive member 101, is formed with a bent shape, and the second groove 112, which is formed on the second conductive member 102, is formed with a bent shape. Further, the first conductor strip 141 is also formed with a bent shape in conformity with the first groove 111 and the second groove 112. The first conductive via row 151 and the second conductive via row 152 are formed in the substrate 103 along the first groove 111 and the second groove 112. Therefore, the bend can be formed without working the substrate 103 into a special shape. Accordingly, it is possible to easily form a rectangular coaxial line even for the case where the frequency used is high.

As has been described heretofore, the rectangular coaxial line 100 of the first embodiment has the structure where the substrate 103 is sandwiched between the first conductive member 101 and the second conductive member 102, the substrate 103 having the first conductor strip 141, the first conductive via row 151, the second conductive via row 152, the first conductor pattern 161, the second conductor pattern 162, the third conductor pattern 163, and the fourth conductor pattern 164, the first conductive member 101 having the first groove 111, the second conductive member 102 having the second groove 112. With such a structure, the first conductive member 101 and the second conductive member 102 are made electrically connected and hence, leakage from the rectangular coaxial line can be suppressed whereby it is possible to achieve a transmission line with a low loss.

Further, in the rectangular coaxial line 100 of the first embodiment, an electric field is not easily concentrated in the substrate compared with a printed circuit board transmission line, and the electric field is dispersed also into the first groove 111 and the second groove 112. Therefore, the rectangular coaxial line 100 can be operated as a transmission line with a lower loss compared with the printed circuit board transmission line. Further, it is possible to suppress the gradient (deviation in the rotational direction with respect to the y axis) of the substrate 103 in the z direction.

Further, also in a case where the rectangular coaxial line 100 has a discontinuous structure, such as bending, it is sufficient to change the shape of a groove formed on each conductive member, to form a conductor strip and conductive via rows in the substrate along the grooves, and to fix the first conductive member 101 and the second conductive member 102 such that the first conductive member 101 and the second conductive member 102 sandwich the substrate 103. Accordingly, it is possible to easily manufacture a rectangular coaxial line even for the case where the frequency used is high, such as the case of a quasi-millimeter wave band or a millimeter wave band.

### Modification 1

In the first embodiment, the first conductor pattern 161 to the fourth conductor pattern 164 are formed. However, it may be possible to adopt a configuration where the first conductor pattern 161 to the fourth conductor pattern 164 are not formed.

In this case, the first conductive member 101 is connected with one end of the first conductive via row 151 and one end of the second conductive via row 152, and the second conductive member 102 is connected with the other end of the first conductive via row 151 and the other end of the second conductive via row 152. With such a configuration, it is possible to obtain the manner of operation and advantageous effects substantially equal to those in the first embodiment.

It is also possible to adopt a configuration where the first conductor pattern 161 and the third conductor pattern 163 are formed on the first main surface 121 of the substrate 103, but the second conductor pattern 162 and the fourth conductor pattern 164 are not formed on the second main surface 122. It is also possible to adopt a configuration where the first conductor pattern 161 and the third conductor pattern 163 are not formed on the first main surface 121 of the substrate 103, but the second conductor pattern 162 and the fourth conductor pattern 164 are formed on the second main surface 122.

The modification 1 is also applicable to a second embodiment to a sixth embodiment described hereinafter.

### Second Embodiment

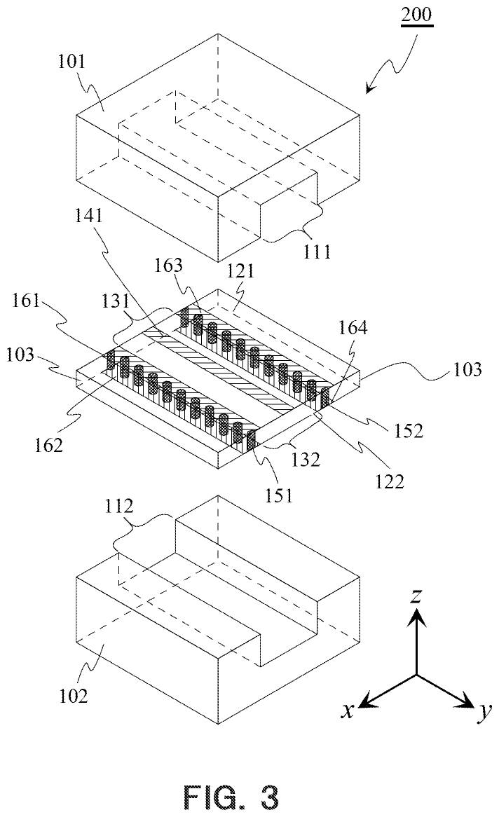

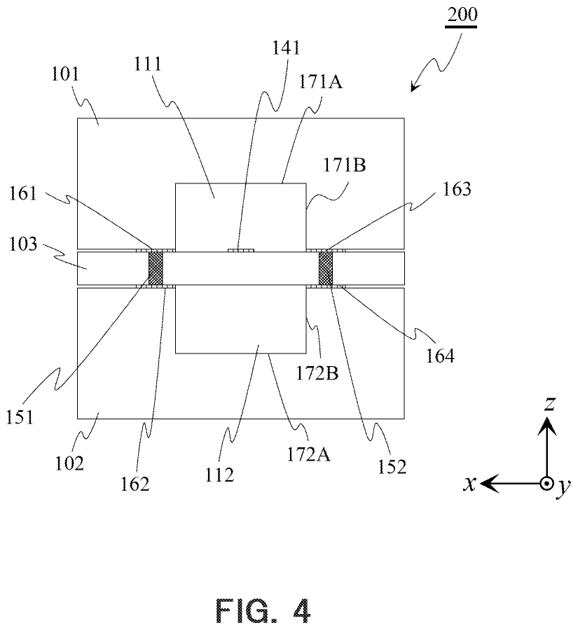

Hereinafter, a rectangular coaxial line 200 which is a coaxial line according to the second embodiment will be described with reference to FIG. 3 and FIG. 4.

FIG. 3 is an exploded perspective view of the rectangular coaxial line 200 which is the coaxial line according to the second embodiment. FIG. 4 is an xz cross-sectional view of the rectangular coaxial line 200 shown in FIG. 3. In the description made hereinafter, components substantially equal to the corresponding components in the first embodiment are given the same reference characters, and the detailed description of such components will be omitted.

In the rectangular coaxial line 200 of the second embodiment, a first conductor pattern 161, a second conductor pattern 162, a third conductor pattern 163, and a fourth conductor pattern 164 are formed into a thin wire shape. A thin wire shape means that the width (the dimension in the x direction) of the first conductor pattern 161 and the second conductor pattern 162 corresponds to the diameter of the conductive vias forming the first conductive via row 151, and the width (the dimension in the x direction) of the third conductor pattern 163 and the fourth conductor pattern 164 corresponds to the diameter of the conductive vias forming the second conductive via row 152. An example of such a correspondence may be a case in which the width (dimension) in the x axis direction of the first conductor pattern 161, the second conductor pattern 162, the third conductor pattern 163, and the fourth conductor pattern 164 has a value of the order of or close to the order of the diameter (the width in the x axis direction) of the conductive vias forming the first conductive via row 151 and the second conductive via row 152. For example, the width in the x axis direction of the first conductor pattern 161, the second conductor pattern 162, the third conductor pattern 163, and the fourth conductor pattern 164 may match or may be larger or smaller than the width of the conductive vias in the x axis direction.

The line widths of the conductor patterns depend on a design rule in a manufacturing process. For example, assume that the conductive vias are formed such that holes are formed and, thereafter, inner surfaces of the holes are plated, and a conductor pattern is formed by etching. In this case, by taking into account any deviation between boring positions and a mask pattern, it is necessary to ensure a line width to the extent that the plating on the inner wall surfaces of the conductive vias is not removed in an etching process.

In the rectangular coaxial line 200 of the second embodiment, the areas of the first conductor pattern 161, the second conductor pattern 162, the third conductor pattern 163, and the fourth conductor pattern 164 are smaller than those in the first embodiment. Therefore, it is possible to ensure conduction points between the respective conductor patterns and the first conductive member 101 and the second conductive member 102 along the first groove 111 and the second groove 112 and hence, transmission loss caused by leakage can be suppressed more than in the first embodiment. That is, when the first conductor pattern 161, the second conductor pattern 162, the third conductor pattern 163, and the fourth conductor pattern 164 have large areas, each conductor pattern may vary in thickness (dimension in the z direction) depending on location. In this case, the conduction point between the first conductive member 101 and the first conductor pattern 161 may be away from the first groove 111, and the conduction point between the first conductive member 101 and the third conductor pattern 163 may be away from the first groove 111. In the same manner, the conduction point between the second conductive member 102 and the second conductor pattern 162 may be away from the second groove 112, and the conduction point between the second conductive member 102 and the fourth conductor pattern 164 may be away from the second groove 112. In this case, radio waves that propagate through the inside of the rectangular coaxial line easily leaks through the gap formed between the first conductive member 101 and the second conductive member 102, thus increasing transmission loss. Further, in some cases, an unnecessary resonance phenomenon may unexpectedly occur. In contrast, in the second embodiment, the respective conductor patterns have a thin wire shape, thus having small areas and hence, it is possible to ensure a conduction point between the first conductive member 101 and the second conductive member 102 near the first groove 111 and the second groove 112. Accordingly, transmission loss caused by leakage of radio waves can be suppressed with more certainty compared with the first embodiment.

In FIG. 3 and FIG. 4, the rectangular coaxial line 200 is illustrated as a linear transmission line extending in the y axis direction. However, in the same manner as the first embodiment, the rectangular coaxial line 200 may have at least one of either a bend or a branch. For example, in the case of forming the bend, in the same manner as the first embodiment, the first groove 111 and the second groove 112 are formed with a bent shape. The first conductor strip 141 is also formed with a bent shape in conformity with the first groove 111 and the second groove 112. The first conductive via row 151 and the second conductive via row 152 are formed along the first groove 111 and the second groove 112, and the first conductor pattern 161, the second conductor pattern 162, the third conductor pattern 163, and the fourth conductor pattern 164 are formed into a thin wire shape along the first groove 111 and the second groove 112. Therefore, the bend can be formed without working the substrate 103 into a special shape and hence, it is possible to easily form a rectangular coaxial line even for the case where the frequency used is high.

As has been described heretofore, in the rectangular coaxial line 200 of the second embodiment, the first conductor pattern 161, the second conductor pattern 162, the third conductor pattern 163, and the fourth conductor pattern 164 are formed into a thin wire shape and hence, it is possible to ensure the conduction point between the first conductive member 101 and the second conductive member 102 along the first groove 111 and the second groove 112. Accordingly, it is possible to further suppress transmission loss caused by leakage. Further, in the same manner as the first embodiment, it is possible to easily manufacture the rectangular coaxial line 200.

### Third Embodiment

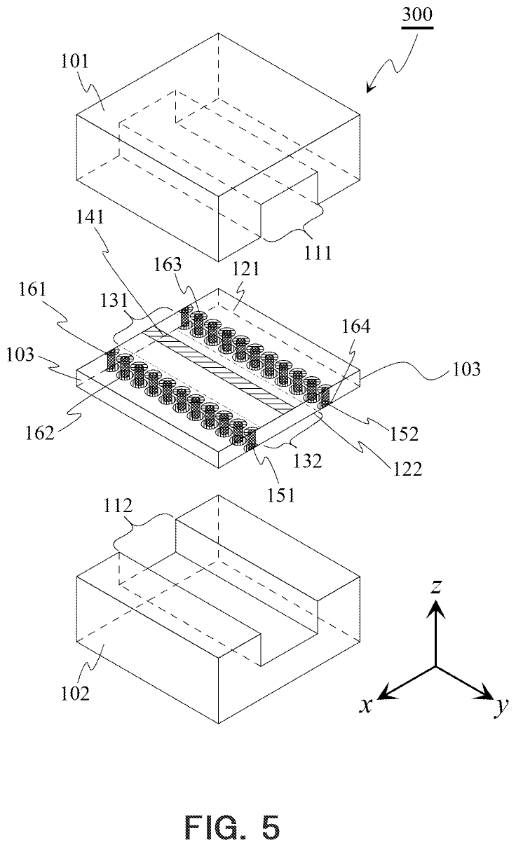

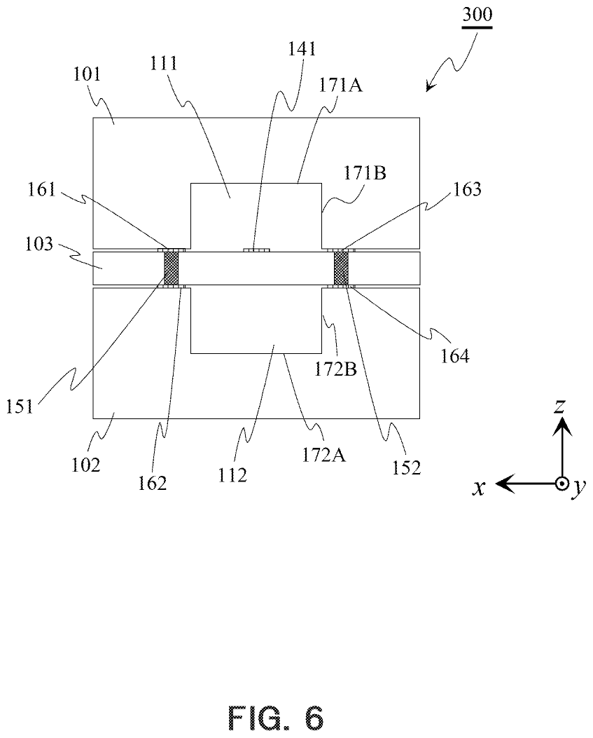

Hereinafter, a rectangular coaxial line 300 which is a coaxial line according to a third embodiment will be described with reference to FIG. 5 and FIG. 6. FIG. 5 is an exploded perspective view of the rectangular coaxial line 300 which is the coaxial line according to the third embodiment. FIG. 6 is an xz cross-sectional view of the rectangular coaxial line 300 shown in FIG. 5. In the description made hereinafter, components substantially equal to the corresponding components in the first embodiment are given the same reference characters, and the detailed description of such components will be omitted.

In the rectangular coaxial line 300 of the third embodiment, each of the first conductor pattern 161, the second conductor pattern 162, the third conductor pattern 163, and the fourth conductor pattern 164 is formed in a state of being physically separated into a plurality of patterns. That is, the first conductor pattern 161 is separated into a plurality of first patterns, the second conductor pattern 162 is separated into a plurality of second patterns, the third conductor pattern 163 is separated into a plurality of third patterns, and the fourth conductor pattern 164 is separated into a plurality of fourth patterns. Specifically, the first patterns are separate from each other to form spaces among the first patterns. The second patterns are separate from each other to form spaces among the second patterns. The third patterns are separate from each other to form spaces among the third patterns. The fourth patterns are separate from each other to form spaces among the fourth patterns. Each pattern of the first conductor pattern 161 and each pattern of the second conductor pattern 162 have a land shape having a width on the order of the diameter (the width in the y axis direction) of each conductive via forming the first conductive via row 151, or a width close to the above-mentioned width. In the same manner, each pattern of the third conductor pattern 163 and each pattern of the fourth conductor pattern 164 have a land shape having a width on the order of the diameter (the width in the y axis direction) of each conductive via forming the second conductive via row 152, or a width close to the above-mentioned width.

In an example shown in the drawing, each pattern having a land shape is connected to only one conductive via. However, each pattern having a land shape may be connected to a plurality of conductive vias disposed adjacent to each other. The patterns having a land shape may include a combination of various patterns, such as a pattern connected to only one conductive via, a pattern connected to two conductive vias disposed adjacent to each other in the y axis direction, and a pattern connected to three conductive vias disposed adjacent to each other in the y axis direction. In the example shown in the drawing, the land has a circular shape. However, the land may have a quadrangular shape, a polygonal shape, an elliptical shape, or any of other shapes.

The dimension of the land depends on a design rule in a manufacturing process. For example, assume a case where conductive vias are formed such that holes are formed and, thereafter, inner wall surfaces of the holes are plated, and a conductor pattern is formed by etching. In such a case, by taking into account any deviation between boring positions and a mask pattern, it is necessary to ensure the dimension of the land to the extent that the plating on the inner wall surfaces of the conductive vias is not removed in an etching process.

In the rectangular coaxial line 300 of the third embodiment, each of the first conductor pattern 161, the second conductor pattern 162, the third conductor pattern 163, and the fourth conductor pattern 164 is formed in a discrete state and hence, it is possible to ensure conduction points between the respective conductor patterns and the first conductive member 101 and the second conductive member 102 along (corresponding to) the first groove 111 and the second groove 112. Accordingly, in the same manner as the second embodiment, it is possible to further suppress transmission loss caused by leakage.

In FIG. 5 and FIG. 6, the rectangular coaxial line 300 is a linear transmission line extending in the y axis direction. However, the rectangular coaxial line 300 may have at least one of either a bend or a branch. For example, in the case of forming the bend, in the same manner as the first embodiment, the first groove 111 and the second groove 112 are formed with a bent shape. The first conductor strip 141 is also formed with a bent shape in conformity with the first groove 111 and the second groove 112. The first conductive via row 151 and the second conductive via row 152 are formed in the substrate 103 along the first groove 111 and the second groove 112. Each of the first conductor pattern 161, the second conductor pattern 162, the third conductor pattern 163, and the fourth conductor pattern 164 is formed into land shapes along the first groove 111 and the second groove 112. Therefore, the bend can be formed without working the substrate 103 into a special shape and hence, it is possible to easily form a rectangular coaxial line even for the case where the frequency used is high.

As has been described heretofore, in the rectangular coaxial line 300 of the third embodiment, each of the first conductor pattern 161, the second conductor pattern 162, the third conductor pattern 163, and the fourth conductor pattern 164 is formed in a discrete state and hence, it is possible to ensure the conduction points between the conductor patterns and the first conductive member 101 and the second conductive member 102 along the first groove 111 and the second groove 112. Accordingly, it is possible to further suppress transmission loss caused by leakage. Further, in the same manner as the first embodiment, it is possible to easily manufacture the rectangular coaxial line 300.

### Fourth Embodiment

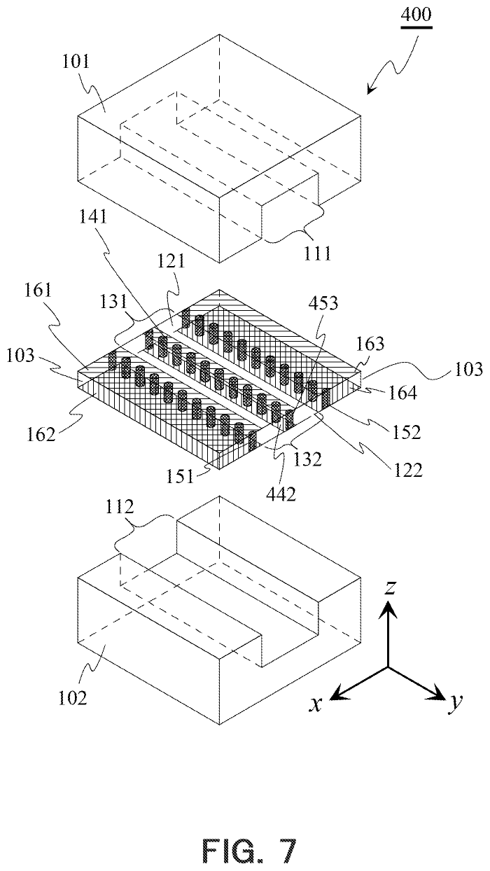

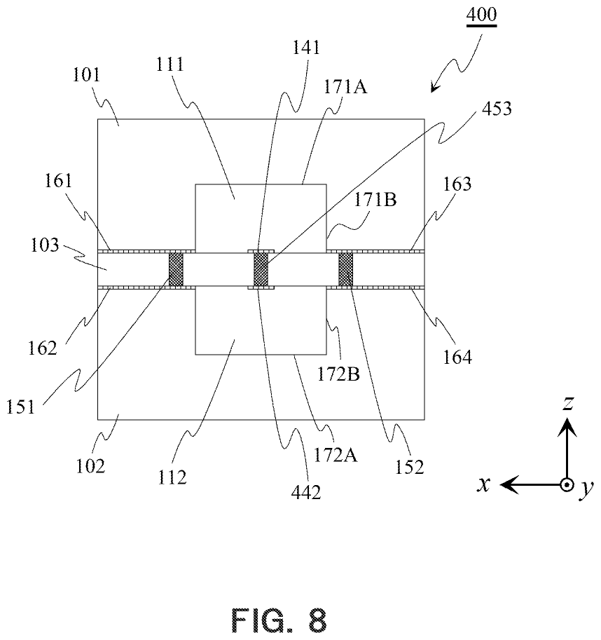

Hereinafter, a rectangular coaxial line 400 which is a coaxial line according to a fourth embodiment will be described with reference to FIG. 7 and FIG. 8. FIG. 7 is an exploded perspective view of the rectangular coaxial line 400 which is the coaxial line according to the fourth embodiment. FIG. 8 is an xz cross-sectional view of the rectangular coaxial line 400 shown in FIG. 7. In the description made hereinafter, components substantially equal to the corresponding components in the first embodiment are given the same reference characters, and the detailed description of such components will be omitted.

In the rectangular coaxial line 400 of the fourth embodiment, a second conductor strip 442 which is a second transmission conductor is provided between the first conductive via row 151 and the second conductive via row 152. To be more specific, the second conductor strip 442 is provided in the second region 132. A third conductive via row 453 is formed in the substrate 103 so as to make the first conductor strip 141 and the second conductor strip 442 electrically connected. The third conductive via row 453 is formed of a plurality of third conductors that penetrate through the substrate 103 from the first main surface 121 to the second main surface 122, and electrically connect the first conductor strip 141 and the second conductor strip 442 with each other.

The second conductor strip 442 is manufactured by a method substantially equal to a method for manufacturing the first conductor strip 141. Further, the third conductive via row 453 is manufactured by a method substantially equal to a method for manufacturing the first conductive via row 151 or the second conductive via row 152.

For example, the second conductor strip 442 has the same shape or substantially the same shape as the first conductor strip 141. However, the second conductor strip 442 may have a shape different from the shape of the first conductor strip 141. The diameter of each conductive via forming the third conductive via row 453 is smaller than the wavelength. Further, the interval between the conductive vias is also smaller than the wavelength.

In the rectangular coaxial line 400 of the fourth embodiment, the first conductor strip 141, the second conductor strip 442, and the third conductive via row 453 are equivalently operated as an inner conductor having a block shape. Therefore, it becomes further difficult for an electric field to be concentrated in the substrate 103 compared with the rectangular coaxial line 100 of the first embodiment and hence, it is possible to further reduce transmission loss. Specifically, in the rectangular coaxial line 100 of the first embodiment, an electric field directed from the inner conductor toward the bottom surface of the second groove 112, which is the outer conductor, is generated in a region in the substrate 103 directly below (on the negative side along the z axis of) the first conductor strip 141. In contrast, in the rectangular coaxial line 400 of the fourth embodiment, an electric field directed from the inner conductor toward the bottom surface 172A of the second groove, which is the outer conductor, is generated between the second conductor strip 442 and the bottom surface of the second groove 112. Therefore, it is possible to further reduce a dielectric loss generated in the substrate 103.

In FIG. 7 and FIG. 8, the rectangular coaxial line 400 is a linear transmission line extending in the y axis direction. However, the rectangular coaxial line 400 may have at least one of either a bend or a branch. For example, in the case of forming the bend, in the same manner as the first embodiment, the first groove 111 and the second groove 112 are formed with a bent shape. The first conductor strip 141 is also formed with a bent shape in conformity with the first groove 111 and the second groove 112. The first conductive via row 151 and the second conductive via row 152 are formed in the substrate 103 along the first groove 111 and the second groove 112. The first conductor strip 141 is formed with a bent shape in conformity with the first groove 111 and the second groove 112. The third conductive via row 453 is formed to connect the first conductor strip 141 and the second conductor strip 442 with each other. Accordingly, the bend can be formed without working the substrate 103 into a special shape and hence, it is possible to easily form a rectangular coaxial line even for the case where the frequency used is high.

As has been described heretofore, in the rectangular coaxial line 400 of the fourth embodiment, the first conductor strip 141, the second conductor strip 442, and the third conductive via row 453 are equivalently operated as the inner conductor having a block shape and hence, it becomes difficult for an electric field to be concentrated in the substrate 103. Accordingly, it is possible to reduce a dielectric loss, so that transmission loss can be further reduced.

### Fifth Embodiment

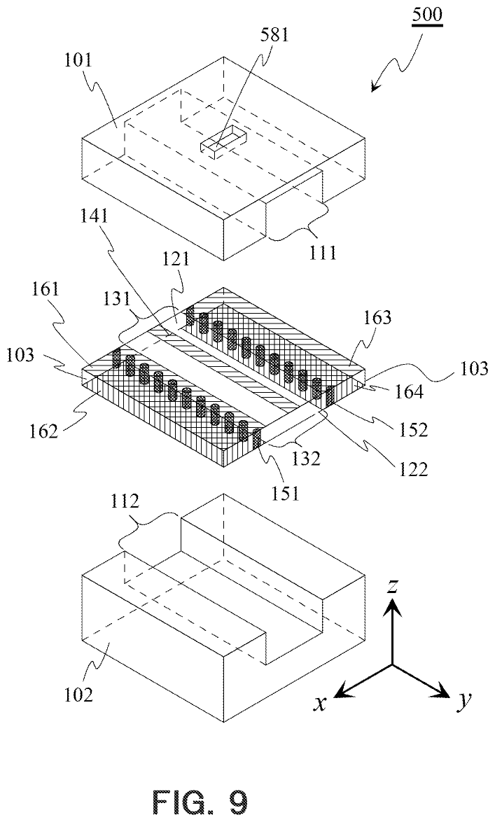

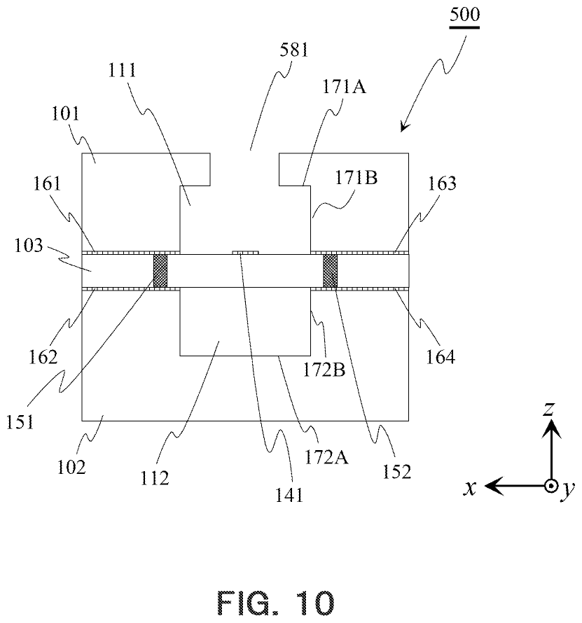

Hereinafter, a rectangular coaxial line 500 which is a coaxial line according to a fifth embodiment will be described with reference to FIG. 9 and FIG. 10. FIG. 9 is an exploded perspective view of the rectangular coaxial line 500 which is the coaxial line according to the fifth embodiment. FIG. 10 is an xz cross-sectional view of the rectangular coaxial line 500 shown in FIG. 9. In the description made hereinafter, components substantially equal to the corresponding components in the first embodiment are given the same reference characters, and the detailed description of such components will be omitted.

The rectangular coaxial line 500 of the fifth embodiment has an opening 581 that penetrates through the first conductive member 101 to the first groove 111 from the surface (fourth surface) on the opposite side from the surface (third surface) having the first groove 111. That is, the rectangular coaxial line 500 has the opening 581 that partially penetrates the surface (third surface) and the fourth surface of the first conductive member 101, the surface (third surface) of the first conductive member 101 facing the first main surface 121 of the substrate 103, the fourth surface being on the opposite side from the surface (third surface) of the first conductive member 101.

In the drawings, the opening 581 is formed with the longitudinal direction of the opening 581 extending in a direction orthogonal to the y axis. That is, an angle formed between the longitudinal direction of the opening 581 and the y axis is 90 degrees. However, the angle formed between the longitudinal direction of the opening 581 and the y axis may be an angle other than 90 degrees. Further, in the drawing, the opening 581 has a cuboid shape having uniform dimensions in the yz plane. However, by taking into account manufacturing, the corners of the opening 581 may be rounded, or the opening 581 may have draft.

The opening 581 is operated as a slot antenna, and transmits and receives radio waves through the opening 581. When the dimension of the opening 581 in the longitudinal direction is substantially equivalent to a half wavelength, the opening 581 can efficiently emit radio waves to the outside of the rectangular coaxial line 500. Accordingly, it is possible to provide a rectangular coaxial line having the function of a highly-efficient antenna. In other words, by using the rectangular coaxial line as a power feed line of an antenna, it is possible to achieve a high efficiency antenna.

In FIG. 9 and FIG. 10, the rectangular coaxial line 500 of the fifth embodiment is a linear transmission line extending in the y axis direction, and has only one opening 581. However, a plurality of openings 581 may be formed in series at intervals in y axis direction. With such a configuration, it is possible to form a rectangular coaxial line having the function of a series-fed array antenna. Alternatively, it may be also possible to form a rectangular coaxial line having the function of a corporate feeding array antenna by branching a rectangular coaxial line into a plurality of sections, and by forming an opening at the distal end of each branched section.

As has been described heretofore, in the rectangular coaxial line 500 of the fifth embodiment, the opening 581 is formed in the first conductive member 101 such that the opening 581 reaches the first groove 111 from the surface (fourth surface) on the opposite side from the surface (third surface) having the first groove 111. The opening 581 is caused to be operated as a slot antenna. With such a configuration, it is possible to form a rectangular coaxial line having the function of a highly-efficient antenna.

### Sixth Embodiment

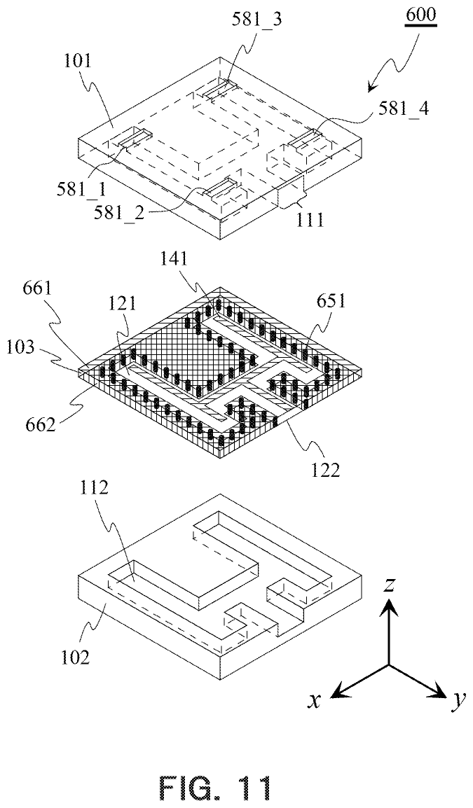

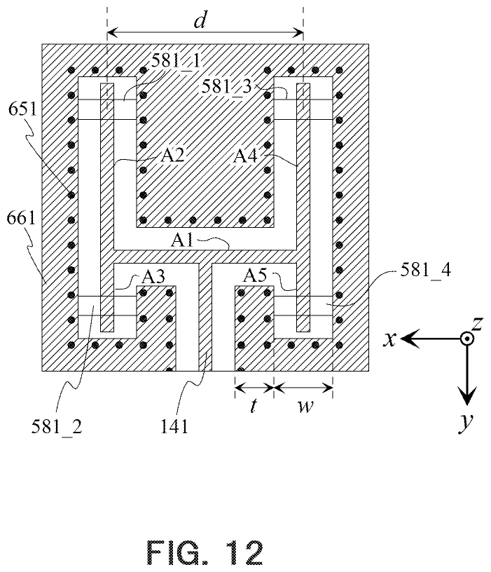

Hereinafter, a rectangular coaxial line (array antenna) 600 which is a coaxial line according to a sixth embodiment will be described with reference to FIG. 11 and FIG. 12. FIG. 11 is an exploded perspective view of the rectangular coaxial line 600 which is the coaxial line according to the sixth embodiment. FIG. 12 is a top plan view of the rectangular coaxial line 600 shown in FIG. 11. In the description made hereinafter, components substantially equal to the corresponding components in the fifth embodiment are given the same reference characters, and the detailed description of such components will be omitted.

The rectangular coaxial line 600 of the sixth embodiment has a configuration where T-junctions are cascaded, each T-junction being formed using a rectangular coaxial line substantially equal to that in the fifth embodiment. Two T-junctions are cascaded, thus forming four distribution circuits in total. The distal end portions of the distribution circuits respectively have openings (a first opening 581_1, a second opening 581_2, a third opening 581_3, a fourth opening 581_4).

In other words, the rectangular coaxial line 600 is a slot array antenna (two-dimensional array antenna) having elements in a two-by-two array.

As shown in FIG. 12, a first conductor strip 141 (first transmission conductor) includes a first transmitting part A1, a second transmitting part A2, a third transmitting part A3, a fourth transmitting part A4, and a fifth transmitting part A5. The second transmitting part A2 is branched from the first transmitting part A1. The third transmitting part A3 is branched from the first transmitting part A1. The fourth transmitting part A4 is branched from the first transmitting part A1. The fifth transmitting part A5 is branched from the first transmitting part A1. The first transmitting part A1, the second transmitting part A2, and the third transmitting part A3 form the first T-junction, and the first transmitting part A1, the fourth transmitting part A4, and the fifth transmitting part A5 form the second T-junction. These two T-junctions are cascaded.

In a substrate 103, a conductive via row 651 is arranged around the first conductor strip 141, to be more specific, around the first region 131 and the second region 132. The conductive via row 651 is formed of a plurality of conductors that penetrate through the substrate 103 from a first main surface 121 to a second main surface 122 to make a first conductor pattern 661 and a second conductor pattern 662 electrically connected.

The first conductor pattern 661 is formed on the first main surface 121 of the substrate 103 in a region other than the first region 131. The second conductor pattern 662 is formed on the second main surface 122 of the substrate 103 in a region other than the second region 132.

A first conductive member 101 uses a first groove 111 to form a space between the first conductive member 101 and the first conductor strip 141. Further, the first conductive member 101 is electrically connected with a plurality of conductors of the conductive via row 651. That is, the first conductive member 101 is a first enclosure member that forms a space along the first conductor strip 141, the space surrounding the first conductor strip 141 in the negative direction along the z axis (the direction in which the first conductive member 101 faces the first main surface 121). The first enclosure member electrically connects the plurality of conductors of the conductive via row 651 with each other. Of the surfaces of the first conductive member 101, the surface having the first groove 111 corresponds to a lower surface (third surface) facing the first main surface 121 of the substrate 103. Of the surfaces of the first conductive member 101, the surface on the opposite side from the lower surface corresponds to an upper surface (fourth surface).

The second conductive member 102 uses the second groove 112 to form a space between the second conductive member 102 and a region on the second main surface 122 of the substrate 103 corresponding to the first conductor strip 141. Further, the second conductive member 102 is electrically connected with the plurality of conductors of the conductive via row 651. That is, the second conductive member 102 is a second enclosure member that forms a space along the above-mentioned region, where the second main surface 122 faces the first conductor strip 141, the space surrounding the above-mentioned region, where the second main surface 122 faces the first conductor strip 141, from the positive direction (the second direction in which the second conductive member 102 faces the second main surface 122) along the z axis. The second enclosure member electrically connects the plurality of conductors of the conductive via row 651 with each other.

The first opening 581_1 is a slot partially penetrating through the first conductive member 101 between the upper surface of the first conductive member 101 and a portion (first portion) on the lower surface of the first conductive member 101, the portion (first portion) facing the second transmitting part A2.

The second opening 581_2 is a slot partially penetrating through the first conductive member 101 between the upper surface of the first conductive member 101 and a portion (second portion) on the lower surface of the first conductive member 101, the portion (second portion) facing the third transmitting part A3.

The third opening 581_3 is a slot partially penetrating through the first conductive member 101 between the upper surface of the first conductive member 101 and a portion (third portion) on the lower surface of the first conductive member 101, the portion (third portion) facing the fourth transmitting part A4.

The fourth opening 581_4 is a slot partially penetrating through the first conductive member 101 between the upper surface of the first conductive member 101 and a portion (fourth portion) on the lower surface of the first conductive member 101, the portion (fourth portion) facing the fifth transmitting part A5.

With the above-mentioned configuration, the first conductive member 101 and the second conductive member 102 are made electrically connected through the first conductor pattern 661, the first conductive via row 151, and the second conductor pattern 662 and hence, in the same manner as the above-mentioned embodiments, it is possible to suppress leakage of radio waves which occurs through a gap formed between the first conductive member 101 and the second conductive member 102. Accordingly, the rectangular coaxial line 600 of the sixth embodiment can achieve an array antenna including a power feed circuit with a low loss.

Assume a case where a two-dimensional array shown in FIG. 11 is formed. In such a case, as shown in FIG. 12, assuming that “d” denotes an interval between radiation elements (interval between openings) in the x direction, “w” denotes the width of the rectangular coaxial line, and “t” denotes the wall thickness between the rectangular coaxial lines, “d” can be expressed as 2w+2t (d=2w+2t). Further, in the array antenna, it is preferable to set the interval between the radiation elements to equal to or less than 1 wavelength so as to suppress a grating lobe. That is, it is preferable that the interval between the first opening 581_1 and the third opening 581_3, and the interval between the second opening 581_2 and the fourth opening 581_4 be set to equal to or less than 1 wavelength of a radio wave. A hollow rectangular waveguide generally known as a waveguide with a low loss has a cutoff frequency and hence, it is necessary to set the width of a wide wall (corresponding to “w” in FIG. 12) to equal to or more than ½ wavelength. Therefore, there is a problem that the interval “d” between the radiation elements exceeds 1 wavelength. In contrast, the rectangular coaxial line of this embodiment is a line of a two conductor system (inner conductor and outer conductor), thus allowing propagation of a quasi TEM (Quasi-Transverse Electro Magnetic) wave, and having no cutoff frequency. Therefore, the width “w” can be set to a dimension equal to or less than ½ wavelength. Accordingly, by selecting “w” that sets “d” to equal to or less than 1 wavelength, it is possible to suppress a grating lobe.

As has been described heretofore, in the rectangular coaxial line 600 of the sixth embodiment, the rectangular coaxial line has no cutoff frequency. Therefore, by setting a tube width that prevents the interval between the radiation elements from exceeding 1 wavelength, it is possible to form a two-dimensional array antenna where loss is low, and a grating lobe does not occur.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

1. A transmission line comprising:
a substrate;
a first transmission conductor on a first surface of the substrate;
a plurality of first conductors penetrating from the first surface of the substrate to a second surface of the substrate on an opposite side from the first surface;
a plurality of second conductors on a side opposite to the plurality of first conductors with respect to the first transmission conductor, and penetrating from the first surface of the substrate to the second surface of the substrate;
a first conductive member forming a first space surrounding the first transmission conductor, and electrically connecting the plurality of first conductors and the plurality of second conductors; and
a second conductive member forming a second space surrounding a region on the second surface of the substrate, the region opposing to the first transmission conductor, and electrically connecting the plurality of first conductors and the plurality of second conductors.

2. The transmission line according to claim 1, wherein
the first conductive member has a first recess on a third surface that faces the first surface of the substrate, the first recess forming the first space surrounding the first transmission conductor, and
the second conductive member has a second recess on a surface that faces the second surface of the substrate, the second recess forming the second space surrounding the region.

3. The transmission line according to claim 1, further comprising:
a first conductor pattern electrically connecting the first conductive member and the plurality of first conductors between the first conductive member and the first surface of the substrate;
a second conductor pattern electrically connecting the second conductive member and the plurality of first conductors between the second conductive member and the second surface of the substrate;
a third conductor pattern electrically connecting the first conductive member and the plurality of second conductors between the first conductive member and the first surface of the substrate; and
a fourth conductor pattern electrically connecting the second conductive member and the plurality of second conductors between the second conductive member and the second surface of the substrate.

4. The transmission line according to claim 3, wherein
the first conductor pattern includes a plurality of first patterns each being connected to a different set of one or more of the plurality of first conductors, the plurality of first patterns being separated from each other,
the second conductor pattern includes a plurality of second patterns each being connected to a different set of one or more of the plurality of first conductors, the plurality of second patterns being separated from each other,
the third conductor pattern includes a plurality of third patterns each being connected to a different set of one or more of the plurality of second conductors, the plurality of third patterns being separated from each other, and
the fourth conductor pattern includes a plurality of fourth patterns each being connected to a different set of one or more of the plurality of second conductors, the plurality of fourth patterns being separated from each other.

5. The transmission line according to claim 3, wherein
the plurality of first conductors are arranged corresponding to a first direction extending along the first transmission conductor,
a width of the first conductor pattern in the first direction has an order of a width of the plurality of first conductors in the first direction,
a width of the second conductor pattern in the first direction has the order of the width of the plurality of first conductors in the first direction,
the plurality of second conductors are arranged corresponding to the first direction,
a width of the third conductor pattern in the first direction has an order of a width of the plurality of second conductors in the first direction, and
a width of the fourth conductor pattern in the first direction has the order of the width of the plurality of second conductors in the first direction.

6. The transmission line according to claim 1, further comprising:
a second transmission conductor on the second surface of the substrate between the plurality of first conductors and the plurality of second conductors; and
a third conductor penetrating from the first surface to the second surface, and electrically connecting the first transmission conductor and the second transmission conductor.

7. The transmission line according to claim 1, further comprising an opening partially penetrating through the first conductive member between a third surface and a fourth surface of the first conductive member, the third surface opposing to the first surface of the substrate, the fourth surface being on an opposite side from the third surface.

8. The transmission line according to claim 7, wherein
a radio wave is transmitted and received through the opening.

9. An electronic apparatus comprising:
a substrate;
a first transmission conductor on a first surface of the substrate, and including a first transmitting part, a second transmitting part, a third transmitting part, a fourth transmitting part, and a fifth transmitting part, the second transmitting part being branched from the first transmitting part, the third transmitting part being branched from the first transmitting part, the fourth transmitting part being branched from the first transmitting part, the fifth transmitting part being branched from the first transmitting part;
a plurality of conductors penetrating from the first surface to a second surface of the substrate, the second surface being on an opposite side from the first surface;
a first conductive member forming a first space surrounding the first transmission conductor, and electrically connected with the plurality of conductors, the first conductive member having a third surface opposing to the first surface of the substrate, and a fourth surface being on an opposite side from the third surface;
a second conductive member forming a second space surrounding a region on the second surface of the substrate, the region opposing to the first transmission conductor, and electrically connected with the plurality of conductors;
a first opening partially penetrating through the first conductive member between the fourth surface and a first portion on the third surface of the first conductive member, the first portion opposing to the second transmitting part,
a second opening partially penetrating through the first conductive member between the fourth surface and a second portion on the third surface of the first conductive member, the second portion opposing to the third transmitting part;
a third opening partially penetrating through the first conductive member between the fourth surface and a third portion on the third surface of the first conductive member, the third portion opposing to the fourth transmitting part; and
a fourth opening partially penetrating through the first conductive member between the fourth surface and a fourth portion on the third surface of the first conductive member, the fourth portion opposing to the fifth transmitting part.

10. The electronic apparatus according to claim 9, wherein
the electronic apparatus is configured to transmit and receive a radio wave through the first opening, the second opening, the third opening, and the fourth opening, and
an interval between the first opening and the third opening, and an interval between the second opening and the fourth opening are equal to or less than 1 wavelength of the radio wave.
